(19) United States
(12) Patent Application Publication
(10) Pub. No.: US 2007/0102190 A1
(43) Pub. Date: May 10, 2007

(54) CIRCUIT DEVICE AND METHOD OF MANUFACTURING THE SAME

(75) Inventor: Noriaki Sakamoto, Gunma (JP)

Correspondence Address: WATCHSTONE P + D, 1250 CONNECTICUT AVENUE, N.W., SUITE 700, WASHINGTON, DC, 20036, US

(73) Assignee: SANYO ELECTRIC CO., LTD., Osaka (JP)

(21) Appl. No.: 11/308,035

(22) Filed: Mar. 3, 2006

(30) Foreign Application Priority Data
Mar. 10, 2005 (JP) 2005-066828

(51) Int. Cl. H05K 1/16

(52) U.S. Cl. 174/260

(57) ABSTRACT

To provide a circuit device having both of high heat releasing property and high breakdown voltage, and a method of manufacturing the same. A first insulating layer is formed on a front surface of a circuit board, and a second insulating layer is formed on a rear surface thereof. Conductive patterns are formed on a surface of the first insulating layer and are fixed to circuit elements. Furthermore, a metal board is stuck to a surface of the second insulating layer. A sealing resin covers front and side surfaces of the circuit board and additionally covers peripheral portions of the rear surface of the circuit board in a manner that the rear surface of the metal board is exposed. Thus, a heat releasing property and a withstand voltage property of the circuit board are ensured.

### CROSS-REFERENCE TO RELATED APPLICATIONS

Priority is claimed to Japanese Patent Application Number JP2005-066828 filed on Mar. 10, 2005, the disclosure of which is incorporated herein by reference in its entirety.

### BACKGROUND OF THE INVENTION

1. Field of the Invention

The present invention relates to a circuit device and a method of manufacturing the same, and more particularly, relates to a circuit device having both of a high heat releasing property and a high withstand voltage property, and a method of manufacturing the same.

2. Description of the Related Art

Referring to FIG. 7, a configuration of a conventional hybrid integrated circuit device 100 will be explained. This technology is described for instance in Japanese Patent Application No. 5-102645. Conductive patterns 103 are formed on a surface of a rectangular board 101 with an insulating layer 102 interposed therebetween. A circuit element 105 is fixed to a desired position of the conductive patterns 103 to form a predetermined electric circuit. As a circuit device, a semiconductor element and a chip element are connected with the conductive patterns 103. Leads 104 are connected with the conductive patterns 103 formed on the peripheral portion of the board 101, and function as an external terminal. A sealing resin 108 has a function to seal the electric circuit formed on the surface of the board 101.

As for a structure of the sealing resin 108, There are two kinds of structures of the sealing resin 108. A first structure is a method that the sealing resin 108 is formed so as to expose a rear surface of the board 101. This structure allows an efficient heat release through the exposed rear surface of the board 101. A second structure is a method that the sealing resin 108 is formed so as to cover the entire board 101 inclusive of the rear surface thereof. According to this structure, a sufficient withstand voltage property and a moisture resistance of the board 101 can be ensured. In FIG. 7, the sealing resin covers the entire board 101 inclusive of the rear surface thereof. A thickness of the sealing resin 108 covering the rear surface of the board 101 is, for example, about 0.5 mm. Especially, in a case where the board 101 is connected with grounding potential, the above second structure is adopted, and thus the board 101 is insulated from an outside.

However, in a case where the sealing resin 108 covers the rear surface of the board 101, there has been a problem that the heat releasing property of the entire device drops due to a low heat conductivity of the sealing resin 108 that covers the rear surface of the board 101.

When the thickness (T5) of the sealing resin 108 covering the rear surface of the board 101 is decreased, it can be expected that the heat releasing property be improved. However, if the thickness T5 of the sealing resin 108 covering the rear surface of the board 101 is set to 0.5 mm or smaller, there arises a problem that the resin cannot completely cover the rear surface of the board 101 in a molding step where the sealing resin 108 is formed through a injection-molding.

Furthermore, when the rear surface of the board 101 is exposed to the outside in order to improve the heat releasing property, there arises a problem that an insulating property between the board 101 and a radiation fin, which comes into contact with the board 101, can not be ensured. There is another problem that the bonding strength between the board 101 and the sealing resin is lowered.

### SUMMARY OF THE INVENTION

The present invention has been accomplished in a view of the above problems. The present invention provides a circuit device having both of a high heat releasing property and a high withstand voltage, and a method of manufacturing the same.

A circuit device according to the present invention includes: a circuit board having a first insulating layer formed on a front surface and a second insulating layer formed on a rear surface; an electric circuit including conductive patterns and a circuit element which are formed on a surface of the first insulating layer; a metal board stuck to a surface of the second insulating layer; and a sealing resin for sealing the electric circuit. The sealing resin covers at least a front surface, side surfaces, and peripheral portions of a rear surface of the circuit board.

Furthermore, in the circuit device according to the present invention, the metal board is stuck by curing a B-stage resin.

Furthermore, in the circuit device according to the present invention, burrs are formed at peripheral edges of the metal board, and a surface opposite to a surface where the burrs protrude is stuck to the surface of the second insulating layer.

Furthermore, in the circuit device according to the present invention, a rear surface of the metal board is exposed from the sealing resin.

Furthermore, in the circuit device according to the present invention, the rear surface of the metal board and the sealing resin form a flat surface.

A manufacturing method of a circuit device according to the present invention includes: sticking a metal board to a rear surface of a circuit board with an insulating layer interposed therebetween and sticking a conductive foil to a front surface of the circuit board with an insulating layer interposed therebetween; patterning the conductive foil to form conductive patterns; configuring an electric circuit including the conductive pattern and a circuit element which are formed on the front surface of the circuit board; and forming a sealing resin using a molding die so as to cover at least the front surface of the circuit board. The metal board is stuck to the rear surface of the circuit board with a B-stage resin interposed therebetween.

In the manufacturing method of a circuit device according to the present invention, the B-stage resin is applied to a front surface of the metal board, and the metal board is stuck to the circuit board through a thermocompression bonding.

Furthermore, in the manufacturing method of a circuit device according to the present invention, the B-stage resin is applied to the front surface of the metal board, the metal board is cut into a desired shape such that burrs are formed on a rear surface of the metal board, and the front surface of the metal board is stuck to the rear surface of the circuit board.

According to the present invention, a metal board is bonded to a rear surface of a circuit device. Accordingly, it is possible to enhance the property of releasing heat that is generated from a circuit element incorporated in the circuit device. In addition, a sealing resin covers the front surface, the side surfaces, and peripheral portions of the rear surface of the circuit board in a manner that a metal board is exposed. Consequently, an anchor effect is generated by the sealing resin, and it is possible to improve the bonding strength between the sealing resin and the circuit board.

Moreover, according to the present invention, the B stage resin is used as a binder for fixing the metal board to the circuit board, whereby the binder can be applied without a leakage and an unevenness, and contributes to an improvement in quality of the circuit device.

Furthermore, the surface opposite to the surface having burrs is adhered to a circuit board surface. Hence, it is possible to prevent a withstand voltage from being deteriorated due to that the burrs damage an insulating layer, and an electricity flows between the metal board and the circuit board.

Furthermore, according to the present invention, the metal board can withstand an externally applied voltage in a state that the rear surface of the metal board is exposed to the outside from a sealing resin. Consequently, it is possible to provide a circuit device having both of a high heat releasing property and a high withstand voltage property.

Furthermore, according to the manufacturing method of the circuit device of the present invention, a sheet-like metal board applied with a B stage resin is stuck to a circuit board. Hence, the total thickness of the metal board and the resin can be made uniform, whereby a dimensional stability of the circuit device can be improved.

Furthermore, according to the manufacturing method of the circuit device of the present invention, the peripheral portions of the rear surface of a circuit board is covered with the sealing resin. Hence, the anchor effect is generated by the sealing resin covering the rear surface, and it is possible to improve the bonding strength between the sealing resin and the circuit board.

### BRIEF DESCRIPTION OF THE DRAWINGS

FIG. 1A is a perspective view showing a circuit device according to a preferred embodiment of the invention, and FIG. 1B is a cross-sectional view thereof;

FIGS. 2A and 2B are cross-sectional views showing a manufacturing method of a circuit device according to the preferred embodiment of the invention;

FIGS. 3A and 3B are cross-sectional views showing a manufacturing method of a circuit device according to the preferred embodiment of the invention;

FIG. 4 is a cross-sectional view showing a manufacturing method of a circuit device according to the preferred embodiment of the invention;

FIGS. 5A to 5C are cross-sectional views showing a manufacturing method of a circuit device according to the preferred embodiment of the invention;

FIGS. 6A and 6B are cross-sectional views showing a manufacturing method of a circuit device according to the preferred embodiment of the invention; and

FIG. 7 is a cross-sectional view showing a conventional hybrid integrated circuit device.

### DESCRIPTION OF THE PREFERRED EMBODIMENT

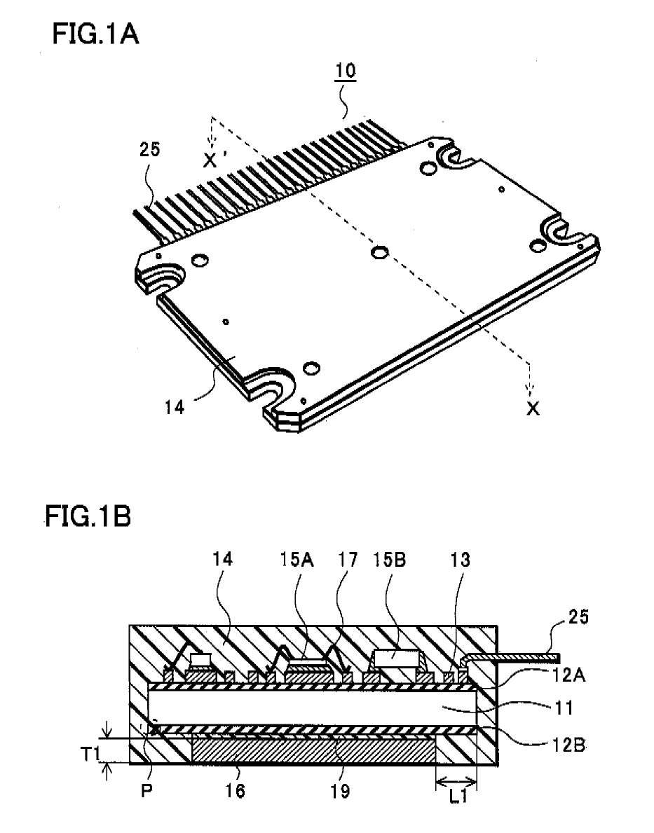

Referring to FIGS. 1A and 1B, a circuit device according to a preferred embodiment of the invention will be explained. Hereinafter, a hybrid integrated circuit device 10 having a plurality of semiconductor chips mounted onto the same board will be explained as an example.

First, a first insulating layer 12A is formed on a front surface of a rectangular circuit board 11. Then, conductive patterns 13 of a predetermined shape are formed on the surface of the first insulating layer 12A. Furthermore, a semiconductor element 15A and a chip element 15B are electrically connected with predetermined positions of the conductive patterns 13 through a solder, a conductive paste, or a thin metal wire. The conductive patterns 13, the semiconductor element 15A, and the chip element 15B which are formed on the front surface of the circuit board 11 are covered with a sealing resin 14. In addition, the sealing resin 14 covers only peripheral portions of the rear surface of the circuit board 11, and thus a metal board 16 stuck to the circuit board 11 is exposed to an outside. To be more specific, the metal board 16, which is exposed from the sealing resin 14, is stuck to a second insulating layer 12B that covers the rear surface of the circuit board 11, with a resin 19 interposed therebetween.

The circuit board 11 is made of a metal such as aluminum or copper. If an aluminum-made board is used as the circuit board 11, for example, the surface of the circuit board 11 is subjected to an alumite treatment or a chemical oxidation. This improves an adhesion property between the first insulating layer 12A and the circuit board 11. Concretely, the circuit board 11 has a dimension: for example, about 61 mm (length)×42.5 mm (width)×1.5 mm (thickness). If a Cu-made circuit board is adopted, its surface may undergo surface roughening for a purpose of improving the adhesion. In particular, it is effective to roughen the rear surface in consideration of the adhesion to the metal board.

The first insulating layer 12A is formed to cover the entire front surface of the circuit board 11. The insulating layer 12 is formed of an epoxy resin highly filled with a filler excellent in a heat conductivity, such as Al₂O₃ or SiO₂. This promotes releasing of heat generated in the incorporated circuit element to the outside through the circuit board 11. A specific thickness of the first insulating layer 12A is, for example, about 50 μm. By the insulating layer 12 having this thickness, a withstand voltage of 4 KV (breakdown voltage) can be ensured.

The second insulating layer 12B is formed to cover the rear surface of the circuit board 11. The second insulating layer 12B may have the same composition as that of the first insulating layer 12A. The rear surface of the circuit board 11 is covered with the second insulating layer 12B and thus a sufficient withstand voltage property of the rear surface of the circuit board 11 can be ensured. Accordingly, even if heat releasing means such as a radiation fin comes into contact with the rear surface of the circuit board 11, the second insulating layer 12B insulates the radiation fin from the circuit board 11.

The conductive patterns are made of a metal such as copper, and formed on the surface of the first insulating layer 12A to realize a predetermined electric circuit. Further, a pad composed of the conductive patterns 13 is formed on one side from which a lead 25 is derived.

Circuit elements such as the semiconductor element 15A and the chip element 15B are fixed to predetermined positions of the conductive patterns 13. As the semiconductor element 15A, a transistor, an LSI chip, or a diode is used. In this example, the semiconductor element 15A is connected with the conductive patterns 13 through a thin metal wire 17. As the chip element 15B, a chip resistor or a chip capacitor is used. To give another example of the chip element 15B, an element having electrode portions on both sides thereof such as an inductance, a thermistor, an antenna, or an oscillator is used. In addition, a resin-seal type package as a circuit element may be fixed to the conductive patterns 13.

The lead 25 is fixed to the pad provided at the peripheral portion of the circuit board 11, and has a function for performing input-output. In the illustrated example, a plurality of the leads 25 are fixed to one side of the board. Further, the leads 25 may be derived from four sides or two sides opposite to each other in the circuit board 11.

Although not shown, the conductive patterns 13 may be formed in multiple layers. Needless to say, an insulating layer is interposed between a first wiring layer and a second wiring layer formed thereon, between the second wiring layer and a third wiring layer formed thereon.

The sealing resin 14 is formed by a transfer-molding using a thermosetting resin. In FIG. 1B, the sealing resin 14 seals the conductive patterns 13, the semiconductor element 15A, the chip element 15B, and the thin metal wire 17. Furthermore, the sealing resin 14 covers the front and side surfaces of the circuit board 11. In addition, on the rear surface of the circuit board 11, the sealing resin 14 covers peripheral portions thereof and the side surfaces of the metal board. The rear surface of the metal board 16 is exposed from the sealing resin 14. In this way, the peripheral portion of the rear surface of the circuit board 11 is covered with the sealing resin 14, thereby an anchor effect is generated to improve a bonding strength between the circuit board 11 and the sealing resin 14. The rear surface of the metal board 16 is exposed, and thus heat generated at the time of driving the semiconductor element 15A can be sufficiently released to the outside through the metal board 16. The second insulating layer 12B and the resin 19 are inferior in a heat conductivity. However, this drawback is overcome by reducing their thicknesses and optionally filling a filler in them.

As a material for the metal board 16, a metal having a sufficient heat conductivity such as copper or aluminum is used. In this embodiment, aluminum is adopted, and the aluminum board is stuck to the rear surface of the circuit board 11 with the resin 19 interposed therebetween. Furthermore, a sheet-like aluminum board (a thickness of about 0.5 mm) coated with the resin 19 of a B-stage (Partially cured) is stuck to the circuit board 11, thereby the unevenness or leakage of the resin is suppressed. Furthermore, the sheet-like board coated with the resin 19 is stuck to the circuit board, thereby the total thickness of the metal board 16 and the resin 19 is uniform, therefore, a dimensional stability of the circuit device is excellent. The sheet-like resin-coated aluminum board is cut into a desired shape through press-cutting. At this time, burrs are formed on one side of the aluminum board; as a result of the press-cutting, the burrs protrude to a surface opposite to a surface coated with the resin 19. This prevents such a situation that the burrs pass through a second insulating layer 18 to come into contact with the circuit board 11, and thereby the withstand voltage is deteriorated.

Furthermore, the sealing resin 14 that covers the peripheral portion of the circuit board 11 and the rear surface of the metal board 16 form the flat rear surface of the circuit device. Thus, the rear surface of the hybrid integrated circuit device 10 can be easily brought into contact with the heat releasing means such as a radiation fin.

In this embodiment, no insulating layer is formed on the rear surface of the metal board.

As described above, in this embodiment, no insulating layer is formed on the rear surface of the metal board 16, but an insulating layer such as an oxide film may be provided. For example, the oxide film is formed of an alumite film prepared through an anodic oxidation. The circuit board 11 has the thickness of about 1.5 mm, while the metal board 16 has the thickness of about 0.5 mm. The thickness of the oxide film is set to, for example, about 10 μm. The oxide film formed on the rear surface of the metal board 16 can protect the exposed rear surface of the metal board 16 from damages.

In this embodiment, the sealing resin 14 covers the peripheral portion of the rear surface of the circuit board 11, therefore, a sufficient withstand voltage property of an end portion P of the circuit board 11 can be ensured. More specifically, the first insulating layer 12A and the second insulating layer 12B are formed on the entire front surface and the entire rear surface of the circuit board 11, respectively. Therefore, sufficient withstand voltage properties in the front and rear surfaces of the circuit board 11 are ensured. In contrast, no resin layer covers the side surfaces of the circuit board 11, and the metal surface is exposed. As a result, in order to securely insulate the circuit board 11 from the outside, it is necessary to prevent the side surfaces (especially, end portion P) of the circuit board 11 from being short-circuited to the outside (chassis or radiation fin fixed to the metal board) through a interface between the circuit board 11 and the sealing resin 14. In this embodiment, the sealing resin 14 is formed on the peripheral portion of the rear surface of the circuit board 11 in a manner that the end portion P is separated from the outside. That is, the sealing resin 14 is formed so as to cover the end portion P. To be more specific, as shown in FIG. 1B, a width of a region covered with the sealing resin 14 is denoted by L1. A length of the width L1 is preferably from about 2 mm to 3 mm or longer although it varies depending on a required withstand voltage. Thus, a sufficient withstand voltage in the end portion P of the circuit board 11 can be ensured. For example, if the length of L1 is 2 mm, the end portion P can withstand a voltage of 2 KV. If the length of L1 is 3 mm, the end portion P can withstand a voltage of 3 KV. Incidentally, a thickness Ti of the sealing resin 14 that covers the rear surface of the circuit board 11 is equivalent to that of the metal board 16, for example, about 0.5 mm. As mentioned above, a sufficient withstand voltage property of the entire circuit board 11 is ensured.

As described above, the circuit device using the circuit board 11 and the metal board excels in the heat releasing property, and is thus applied to an in-vehicle module, for example. In other words, a high-density modularization of a high-output power element, and a circuit for controlling the power element or a microcomputer requires a package having a high heat releasing property and a high-sealing property.

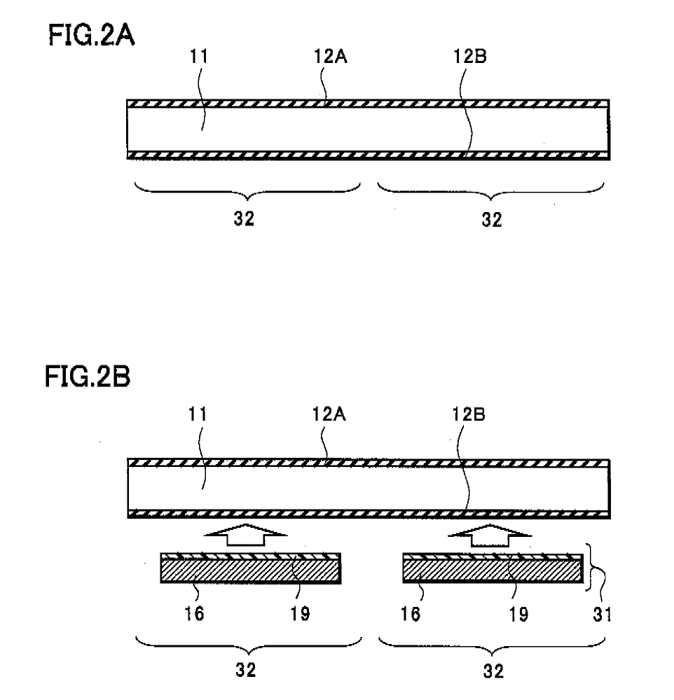

Referring to FIGS. 2A to 6B, a manufacturing method of the hybrid integrated circuit device 10 having the structure described above will be explained.

Referring to FIG. 2A, first, a first insulating layer 12A is formed on the front surface of a circuit board 11, and a second insulating layer 12B is formed on the rear surface of the circuit board.

The circuit board 11 has a size enough to arrange several ten units 32 in matrix thereon. The term “unit” means a portion that constitutes one hybrid integrated circuit device. The circuit board 11 may be formed of aluminum, copper, or iron. As an example of this embodiment, an aluminum board is adopted as the circuit board 11. Furthermore, an aluminum board having front and rear surfaces, which are treated with an alumite treatment, may be adopted. The thickness of the circuit board 11 is about 1.5 mm. In addition, the thicknesses of the first insulating layer 12A and the second insulating layer 12B are about 50 μm to 60 μm. Furthermore, an oxide film may cover the front and the rear surfaces of the circuit board 11. As an example of the oxide film, an alumite film containing Al₂O₃ is adopted and has the thickness of about 1 μm to 5 μm. By forming the thin oxide film as described, a thermal resistance can be reduced.

Referring FIG. 2B, a metal board 16 is stuck to the surface of the second insulating layer 12B with a resin 19 interposed therebetween. In this example, a sheet-like sticking board 31 prepared by applying the B-stage (partially cured) resin 19 to the surface of the metal board 16 having the thickness of about 0.5 mm is used. The resin 19 is, for example, an epoxy resin, and is cured through a heat-pressing. In this embodiment, the resin 19 undergoes the heat-pressing at 150° for about 1 hour, and thus is completely cured to stick the metal board 16 to the surface of the second insulating layer 12B. The sheet-like sticking board 31 is cut into a desired shape and then stuck to a desired position of each unit 32. The resin 19 serves as an adhesive and as an insulating layer. In order to further improve the insulating property, an insulating film may be attached to the resin 19.

Although depending on the thickness of the metal board 16, without being cut, the sticking board may be stuck to each unit, and then cured and etched into a small piece.

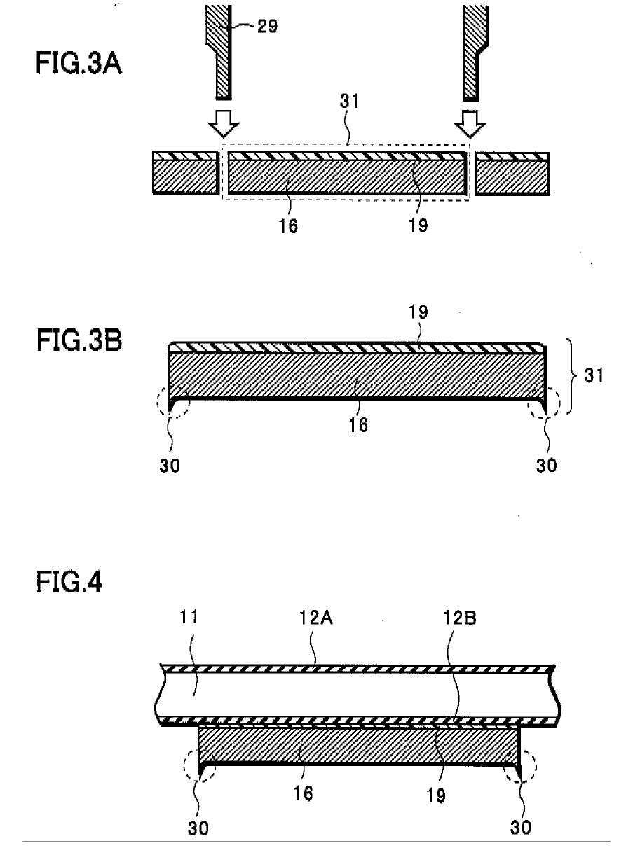

Referring to FIGS. 3A to 4, the sticking board 31 will be explained in detail.

Referring now to FIG. 3A, the sticking board 31 is prepared by applying the resin 19 onto the surface of the metal board 16. Then, the bonding board 31 is press-cut by use of a mold 29 into a desired shape. However, by the press working, burrs are formed at the peripheral edge portions of the metal board 16. Thus, the press working is executed in a manner that the burrs are formed on the surface opposite to the surface coated with the resin 19. As a result, the sticking board 31 of FIG. 3B is formed. As shown in FIG. 4, this aims at preventing such a situation that burrs 30 penetrate the second insulating layer 12B at a time of sticking the sticking board 31 to the circuit board 11, and thus a withstand voltage property in the damaged portion is reduced to generate short-circuiting.

Furthermore, the resin 19 is a B-stage resin and thus excels in a processability. The resin 19 is neither damaged nor peeled off through pressing. Accordingly, reliability in adhesion between the metal board 16 and the circuit board 11 can be improved. Furthermore, even if cracks are generated at the end face of the resin 19, the resin 19 is softened in a thermocompression bonding step, therefore, the cracks can be removed. Thus, the insulating layer made of the resin 19 can be reliably formed on the entire surface of the metal board 16.

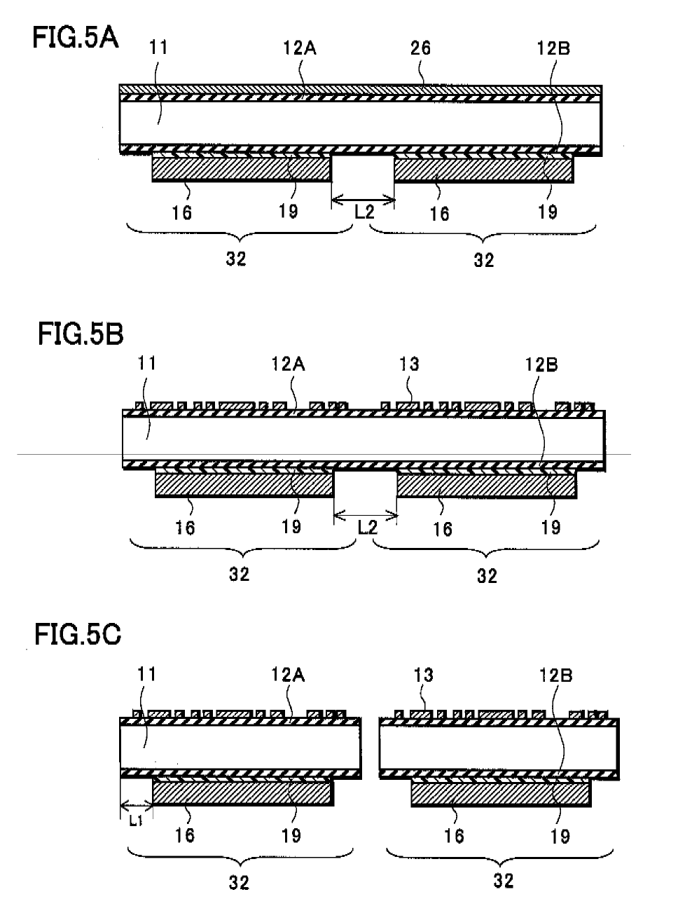

Referring to FIG. 5A, a conductive foil 26 is stuck to the front surface of the circuit board 11. In this example, the conductive foil 26 is stuck to the front surface of the circuit board 11 with the first insulating layer 12A interposed therebetween. As an example, the thickness of the conductive foil 26 is about 70 μm. Furthermore, a distance between the stuck metal boards 16 is set about twice or more as large as the width L1 of FIG. 1B. To be more specific, the distance is about 4 mm to 6 mm.

Referring to FIG. 5B, the conductive foil 26 is patterned through etching and then conductive patterns 13 are formed. The conductive patterns 13 are prepared by etching the conductive foil 26 through a resist formed thereon. In FIG. 5B, the conductive patterns are formed in a single layer. However, the conductive patterns may be formed in two or more layers that are laminated with an insulating layer interposed between two layers.

Referring to FIG. 5C, the circuit boards 11 in each unit 32 are separated. The circuit boards are separated through a press-cutting, a dicing, and a bending. If the circuit boards 11 are separated through the dicing or the bending, an isolation groove may be formed on the front and rear surfaces at the interface between the circuit boards 11 in the respective units 32. This facilitates the separation of the circuit boards.

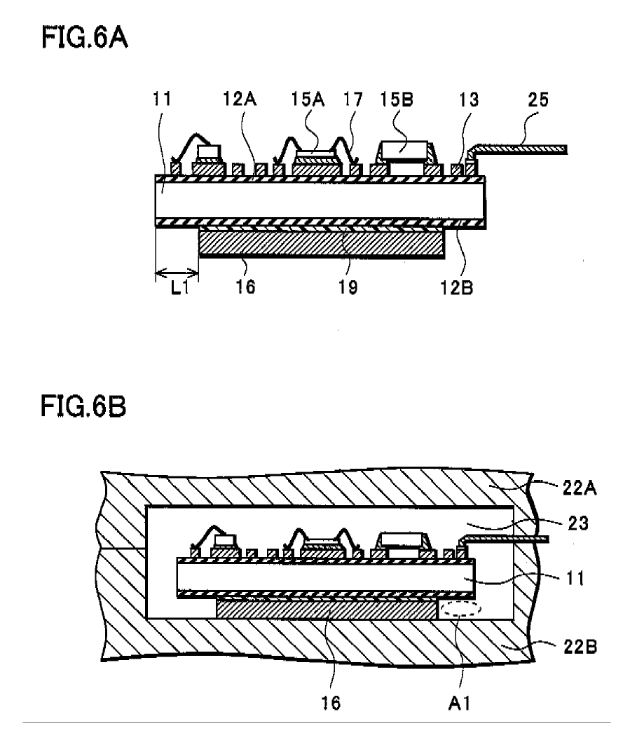

Referring to FIG. 6A, a circuit element is electrically connected with the conductive patterns 13. In this example, the semiconductor element 15A and the chip element 15B are fixed to the conductive patterns. The semiconductor element 15A is electrically connected with the conductive patterns 13A through the thin metal wire 17. This step may be carried out before the separation of the units 32.

Referring to FIG. 6B, a sealing resin is formed to cover the circuit board 11. First, the rear surface of the metal board 16 which is positioned at the undersurface of the circuit board 11 comes into contact with a lower mold 22B. Then, an upper mold 22A comes into contact with the lower mold 22B to encapsulate the circuit board 11 into a cavity 23. A size of the metal board 16 is smaller than that of the circuit board 11, therefore, the peripheral portion of the circuit board 11 is separated from the lower mold 22B so as to have a distance depending on the thickness of the metal board 16. Hence, a sealing resin injected into the cavity 23 reaches a region A1 below the circuit board.

Through the aforementioned steps, the hybrid integrated circuit device 10 as shown in FIGS. 1A and 1B is manufactured.

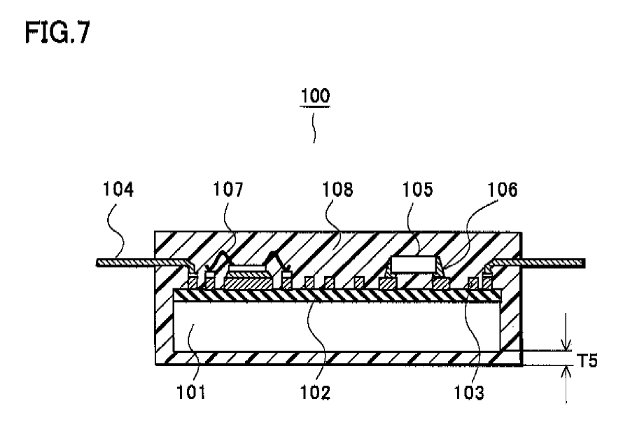

Another advantage will be explained below. As shown in FIG. 7, at a time of sealing a cavity with a resin 108, the resin 108 should be filled in between a lower mold and a board 101. However, the larger the size of circuit board 101 is, the more difficult the impregnation of the resin is. This is because a larger area leads to an increase in a heat releasing property of the board and thus causes the resin having fluidity to start solidifying. However, in the embodiment of the present invention, as shown in FIG. 6B, the metal board 16 limits a sealing area of the resin, and the resin needs only to be filled in a portion surrounding the rear surface of the circuit board. Hence, formation of a portion not filled with the resin is suppressed.

Referring back to FIGS. 1A and 1B, effects of the embodiment of the invention will be explained. In general, when the circuit board 11 is press-cut, the insulating layers 12A and 12B exist at a cutting portion and its surroundings, therefore cracks tend to be generated in such portions. However, the metal board 16 uses the B-stage resin 19, and thus, even if the circuit board is press-cut, the board is hardly cracked. This is because the resin is solidified at room temperatures but is melted when heated, therefore, even if cracks are generated, the cracks are buried with the resin at a time when the resin is heated to be softened and solidified. Accordingly, one of the paths that is short-circuited can be further improved in a withstand voltage property since the generation of the cracks are suppressed. In addition, the B-stage resin 19 is applied throughout the surface with a uniform thickness, therefore, the distance between the circuit board and the metal board can be made uniform across the whole surface without voids. Accordingly, a variation of the heat conductivity can be suppressed.

What is claimed is:

1. A circuit device, comprising:
a circuit board having a first insulating layer formed on a front surface thereof and a second insulating layer formed on a rear surface thereof;
an electric circuit including a conductive pattern and a circuit element which are formed on a surface of the first insulating layer;
a metal board stuck to a surface of the second insulating layer; and
a sealing resin for sealing the electric circuit,
wherein the sealing resin covers at least a front surface, side surfaces, and peripheral portions of a rear surface of the circuit board.

2. The circuit device according to claim 1, wherein the metal board is stuck by curing a B-stage resin.

3. The circuit device according to claim 1, wherein burrs are formed at peripheral edges of the metal board, and a surface opposite to a surface where the burrs protrude is stuck to a surface of the second insulating layer.

4. The circuit device according to claim 1, wherein a rear surface of the metal board is exposed from the sealing resin.

5. The circuit device according to claim 4, wherein the rear surface of the metal board and the sealing resin form a flat surface.

6. A manufacturing method of a circuit device, comprising:
sticking a metal board to a rear surface of a circuit board through an insulating layer interposed therebetween and sticking a conductive foil to a front surface of the circuit board with an insulating layer interposed therebetween;
patterning the conductive foil to form a conductive pattern;
constituting an electric circuit including the conductive pattern and a circuit element which are formed on the front surface of the circuit board; and
forming a sealing resin using a molding die to cover at least the front surface of the circuit board,
wherein the metal board is stuck to the rear surface of the circuit board with a B-stage resin interposed therebetween.

7. The manufacturing method of a circuit device according to claim 6, wherein the B-stage resin is applied to a front surface of the metal board, and the metal board is stuck to the circuit board through thermocompression bonding.

8. The manufacturing method of a circuit device according to claim 6, wherein the B-stage resin is applied to a front surface of the metal board; the metal board is cut into a desired shape in a manner that burrs are formed on a rear surface of the metal board; and the front surface of the metal board is stuck to the rear surface of the circuit board.
